(19) United States
(12) Patent Application Publication
(10) Pub. No.: US 2024/0339320 A1
(43) Pub. Date: Oct. 10, 2024

(54) CERAMIC SUBSTRATE STRUCTURES AND METHODS OF FORMING THE SAME

(71) Applicant: Taiwan Semiconductor Manufacturing Company, Ltd., Hsinchu (TW)

(72) Inventors: Chi-Ming CHEN, Zhubei City (TW); Chia-Shiung TSAI, Hsin-Chu (TW); Chung-Yuan LI, Taichung City (TW)

(21) Appl. No.: 18/297,462

(22) Filed: Apr. 7, 2023

(51) Int. Cl. H01L 21/02; H01L 29/66; H01L 29/778

(52) U.S. Cl. CPC H01L 21/02617; H01L 21/02389; H01L 21/0245; H01L 21/02502; H01L 21/02516; H01L 21/0254; H01L 29/66462; H01L 29/7786; H01L 21/02164; H01L 21/0217; H01L 21/022; H01L 21/02458; H01L 21/02513; H01L 21/02658; H01L 21/31111; H01L 21/32055; H01L 21/32134; H01L 29/2003

(57) ABSTRACT

Using surface activated bonding (SAB) allows direct bonding of a silicon growth seed layer over an aluminum nitride substrate without an intervening oxide layer. The growth seed layer may include p− Si(111) in order to allow for epitaxy of gallium nitride without exacerbating CTE mismatch between silicon and the gallium nitride. As a result, defects in the gallium nitride are reduced, and bowing and cracking of the substrate is reduced, which improves performance of an electronic device including the gallium nitride. Additionally, using SAB is faster than other techniques for forming a growth seed layer as well as conserving power, processing resources, and raw materials that otherwise would have been expended in forming the growth seed layer.

### BACKGROUND

In transistor structures, such as a complementary metal-oxide-semiconductor (CMOS), and in photonic structures, such as a pixel, higher breakdown voltages allow the transistor to function across a wider range of input signals without breaking. Gallium nitride (GaN) can be used as a material for forming a transistor in order to improve breakdown voltage of the transistor because of the high bandgap exhibited by gallium nitride.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A-2C are diagrams of example semiconductor structures described herein.

FIGS. 3A-3Q are diagrams of an example implementation described herein.

FIG. 4 is a diagram of example components of one or more devices of FIG. 1 described herein.

FIG. 5 is a flowchart of an example process associated with forming a semiconductor structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, gallium nitride (GaN) can be used as a material for forming a source, a drain, and/or a channel of a transistor in order to improve breakdown voltage of the transistor because of the high bandgap exhibited by gallium nitride. However, gallium nitride has a different coefficient of thermal expansion (CTE) as compared with silicon (Si), which results in bowing and cracking of silicon substrates that support the transistor.

Accordingly, aluminum nitride (AlN) is often used as a substrate instead of silicon in order to reduce CTE difference. Additionally, a growth seed layer of silicon (e.g., an Si(111) surface, which is a type of silicon that is formed to have a (111) lattice structure or grain orientation) may be formed on the aluminum nitride substrate in order to allow for epitaxy of gallium nitride over the aluminum nitride substrate. However, forming the growth seed layer costs a significant amount of raw materials, power, and processing resources.

Some implementations described herein provide techniques and apparatuses for using surface activated bonding (SAB) to form a silicon growth seed layer over an aluminum nitride substrate. Using SAB enables formation of a growth seed layer of silicon, which allows for epitaxy of gallium nitride over the aluminum nitride substrate. For example, the growth seed layer may include p− Si(111) in order to allow for epitaxy of gallium nitride without exacerbating CTE mismatch between silicon and the gallium nitride. As a result, defects in the drain are reduced, and bowing and cracking of the substrate is reduced, which improves performance of a transistor including the drain. Additionally, using SAB is faster and more cost effective than other techniques for forming a growth seed layer of silicon as well as conserving power, processing resources, and raw materials that otherwise would have been expended in forming the growth seed layer of silicon.

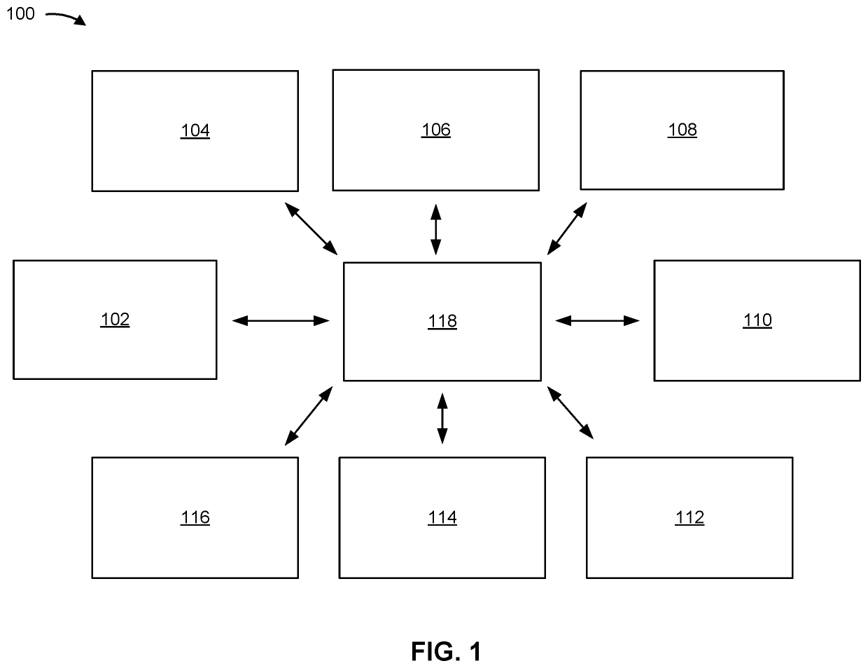

FIG. 1 is a diagram of an example environment 100 in which systems and/or methods described herein may be implemented. As shown in FIG. 1, environment 100 may include a plurality of semiconductor processing tools 102-116 and a wafer/die transport tool 118. The plurality of semiconductor processing tools 102-116 may include a deposition tool 102, an exposure tool 104, a developer tool 106, an etch tool 108, a planarization tool 110, a plating tool 112, an ion implantation tool 114, an annealing tool 116, and/or another semiconductor processing tool. The tools included in the example environment 100 may be included in a semiconductor clean room, a semiconductor foundry, a semiconductor processing and/or manufacturing facility, or another location.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a low pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, an epitaxy tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical polishing (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The ion implantation tool 114 is a semiconductor processing tool that is capable of implanting ions into a substrate. The ion implantation tool 114 may generate ions in an arc chamber from a source material such as a gas or a solid. The source material may be provided into the arc chamber, and an arc voltage is discharged between a cathode and an electrode to produce a plasma containing ions of the source material. One or more extraction electrodes may be used to extract the ions from the plasma in the arc chamber and accelerate the ions to form an ion beam. The ion beam may be directed toward the substrate such that the ions are implanted below the surface of the substrate.

The annealing tool 116 is a semiconductor processing tool that includes a semiconductor processing chamber and one or more devices capable of heating a semiconductor substrate or semiconductor device. For example, the annealing tool 116 may include a rapid thermal annealing (RTA) tool or another type of annealing tool that is capable of heating a semiconductor substrate to cause a reaction between two or more materials or gasses, to cause a material to decompose. As another example, the annealing tool 116 may be configured to heat (e.g., raise or elevate the temperature of) a structure or a layer (or portions thereof) to re-flow the structure or the layer, or to crystallize the structure or the layer, to remove defects such as voids or seams. As another example, the annealing tool 116 may be configured to heat (e.g., raise or elevate the temperature of) a layer (or portions thereof) to enable bonding of two or more semiconductor devices.

The wafer/die transport tool 118 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 118 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

In some implementations, one or more of the semiconductor processing tools 102-116 and/or the wafer/die transport tool 118 may perform one or more semiconductor processing operations described herein. For example, one or more of the semiconductor processing tools 102-116 and/or the wafer/die transport tool 118 may form a supporting layer of amorphous silicon material, sputtered aluminum nitride material, or sputtered silicon material over a first substrate that comprises an aluminum nitride ceramic material; form a silicon seed layer over a second substrate; directly bond the silicon seed layer to the supporting layer; remove the second substrate; and/or form a gallium nitride-based electronic structure over the silicon seed layer, among other examples.

The number and arrangement of tools shown in FIG. 1 are provided as one or more examples. In practice, there may be additional tools, fewer tools, different tools, or differently arranged tools than those shown in FIG. 1. Furthermore, two or more tools shown in FIG. 1 may be implemented within a single tool, or a single tool shown in FIG. 1 may be implemented as multiple, distributed tools. Additionally, or alternatively, a set of tools (e.g., one or more tools) of environment 100 may perform one or more functions described as being performed by another set of tools of environment 100.

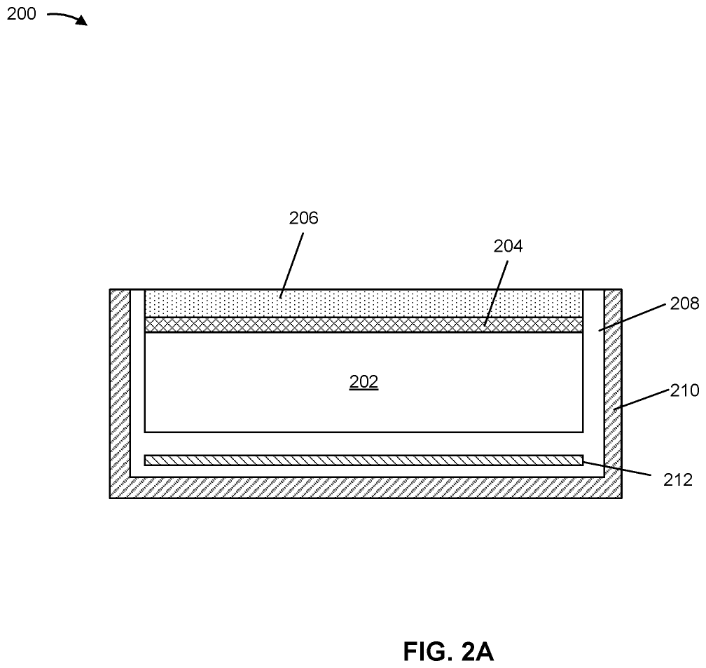

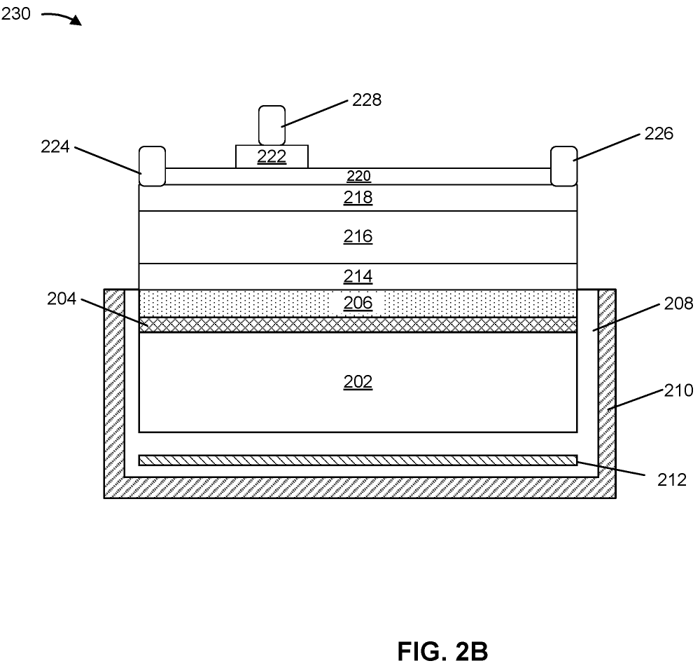

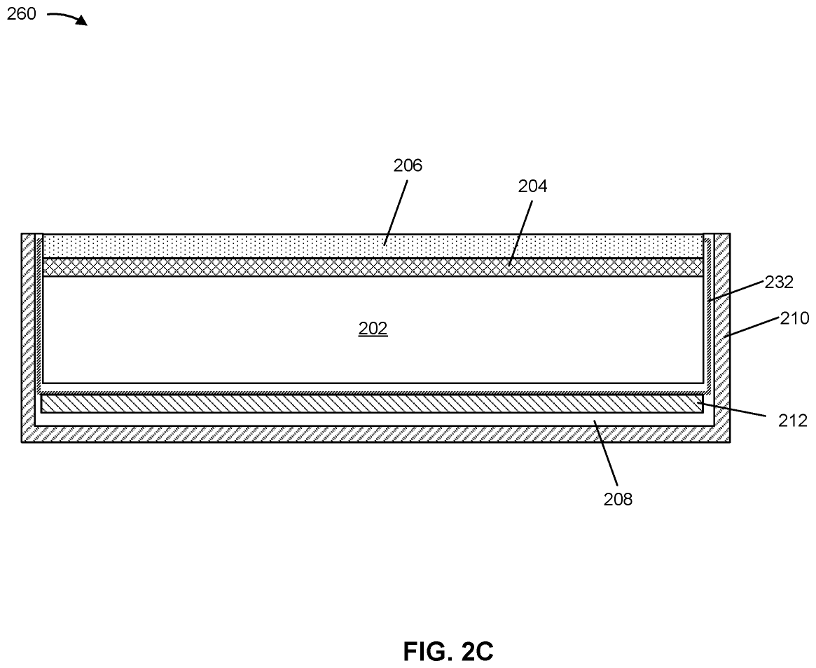

FIG. 2A is a diagram of an example semiconductor structure 200 described herein. The example semiconductor structure 200 is formed using SAB. Using SAB conserves raw materials, power, and processing resources during manufacturing. Additionally, using SAB allows for directly bonding a seed layer 206 to a supporting layer 204 over a ceramic substrate 202. In some implementations, the example semiconductor structure 200 illustrated in FIG. 2A may include, or may be included in, a transistor or another type of electronic device.

The example semiconductor structure 200 may include a substrate 202 that is a ceramic. For example, the substrate 202 may include an aluminum nitride (AlN) ceramic. Because aluminum nitride has a CTE of approximately 5.92×10⁻⁶ inverse Kelvins (K⁻¹), the substrate 202 expands and contracts similarly with gallium nitride (which has a CTE of approximately 5.59×10⁻⁶ K⁻¹). As a result, the substrate 202 is less likely to warp and crack as compared with silicon (which has a CTE of approximately 2.59×10⁻⁶ K⁻¹).

Additionally, aluminum nitride has a thermal conductivity in a range from approximately 2.5 watts per centimeter-kelvin (W/cm·K) to approximately 2.85 W/cm·K. Therefore, the substrate 202 conducts heat away from the gallium nitride more effectively than silicon (which has a thermal conductivity in a range from approximately 1.0 W/cm·K to approximately 1.5 W/cm·K). As a result, heat generated during operation of the example semiconductor structure 200 is more quickly dissipated such that the gallium nitride is less likely to crack or otherwise exhibit defects.

The substrate 202 may have a thickness in a range from approximately 750 micrometers (μm) to approximately 775 μm. By selecting a thickness of at least 750 μm, a gallium nitride-based electronic structure (e.g., as described in connection with FIG. 2B) is physically supported by the substrate 202 without significant strain on the substrate 202. By selecting a thickness of no more than 775 μm, the substrate 202 is small enough to be included in a same package with other electronic devices.

As further shown in FIG. 2A, the example semiconductor structure 200 may include a supporting layer 204. The supporting layer 204 provides adhesion between a growth seed layer 206 and the substrate 202. In some implementations, the supporting layer 204 includes sputtered aluminum nitride. Using sputtered aluminum nitride allows for the supporting layer 204 and the substrate 202 to exhibit matching CTE values, which further reduces chances of the substrate 202 warping and cracking. As an alternative, the supporting layer 204 may include sputtered silicon and/or amorphous silicon (e.g., deposited via CVD). Using silicon conserves power and raw materials and is faster as compared with using aluminum nitride.

The supporting layer 204 may have a thickness in a range from approximately 0.1 μm to approximately 1.0 μm. By selecting a thickness of at least 0.1 μm, the supporting layer 204 provides adhesion between the growth seed layer 206 and the substrate 202. By selecting a thickness of no more than 1.0 μm, any stress caused by CTE difference between the supporting layer 204 and the substrate 202 remains small. However, other values for the thickness of the supporting layer 204 are within the scope of the present disclosure. Additionally, a surface roughness (also referred to as a “roughness average” or “Ra”) of the supporting layer 204 may be less than 0.7 nanometers (nm). By selecting an Ra of no more than 0.7 nm, the growth seed layer 206 adheres to the supporting layer 204. However, other values for the surface roughness of the supporting layer 204 are within the scope of the present disclosure.

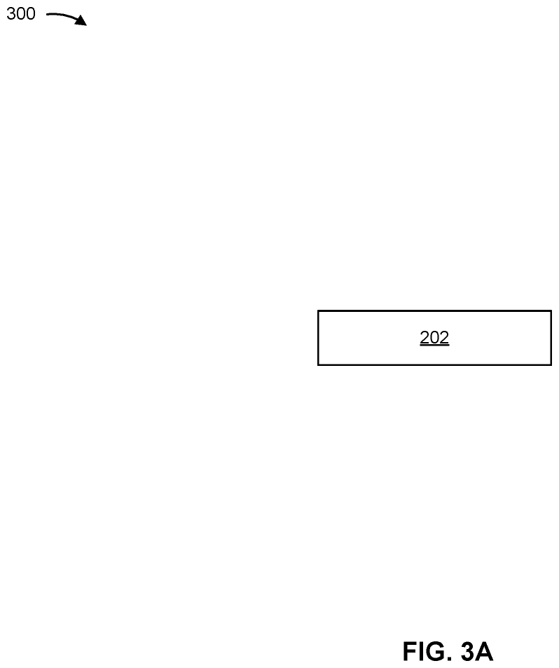

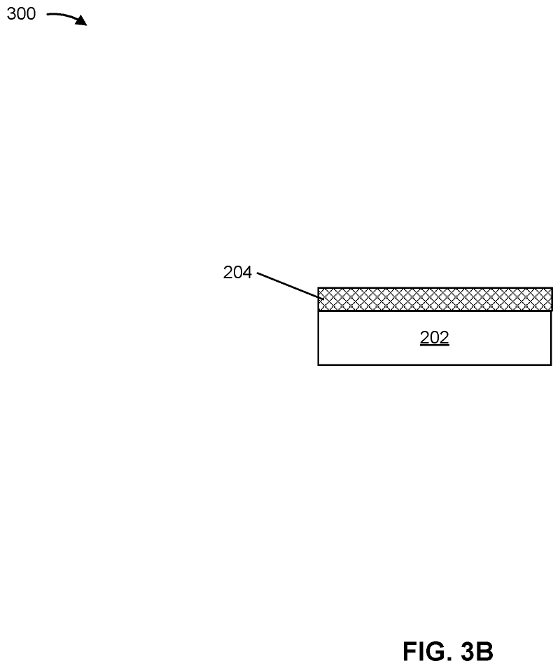

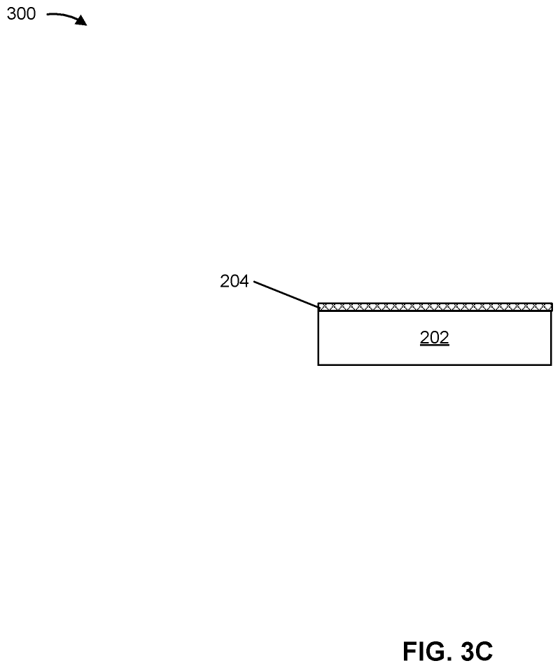

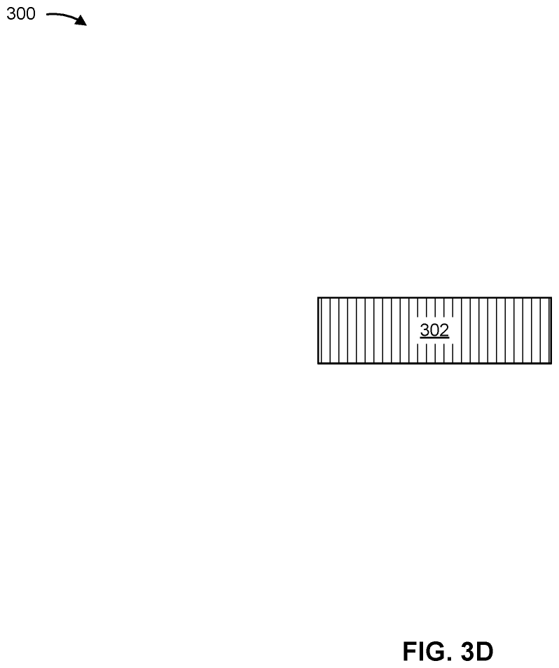

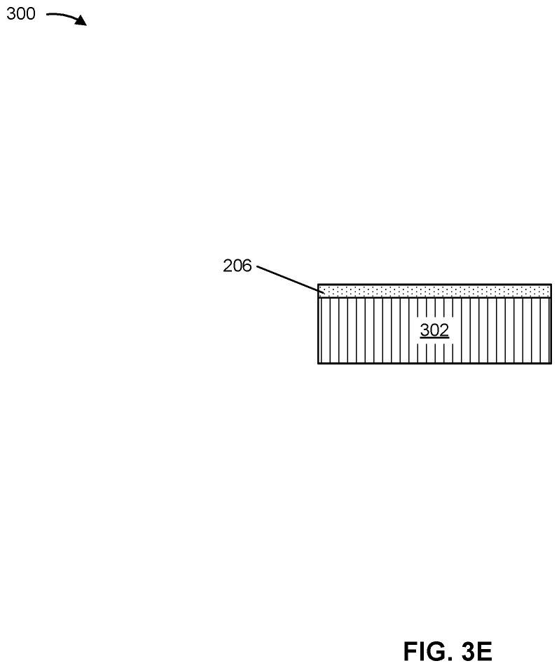

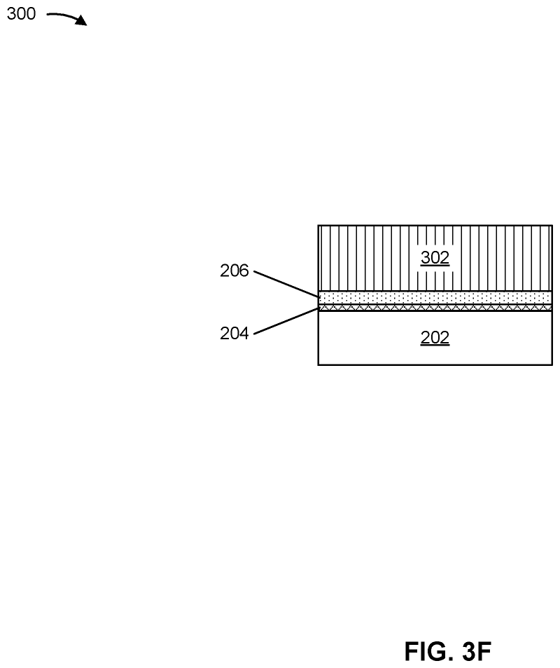

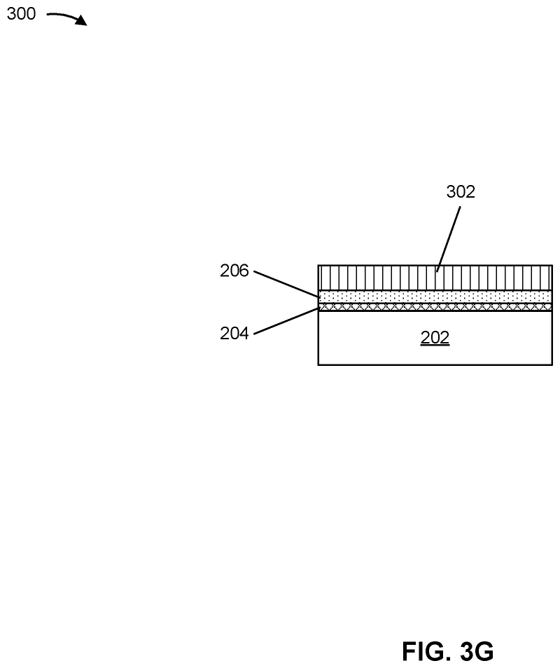

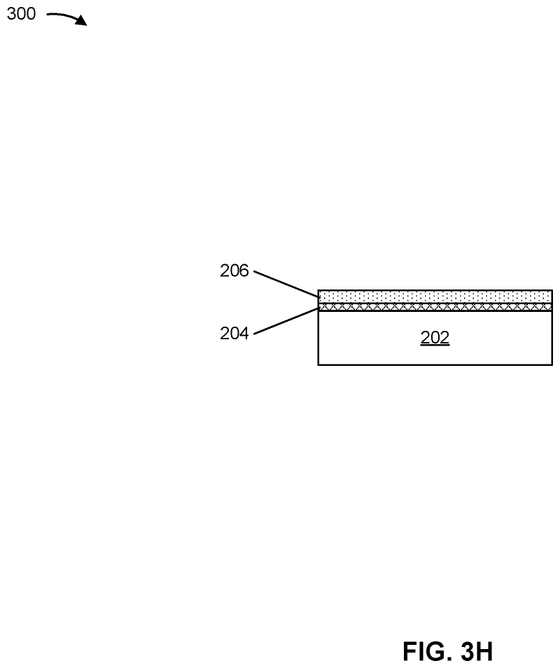

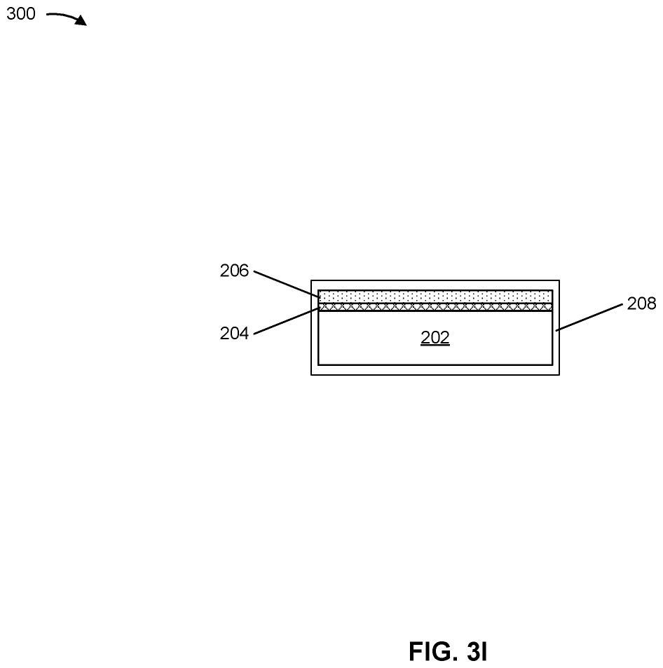

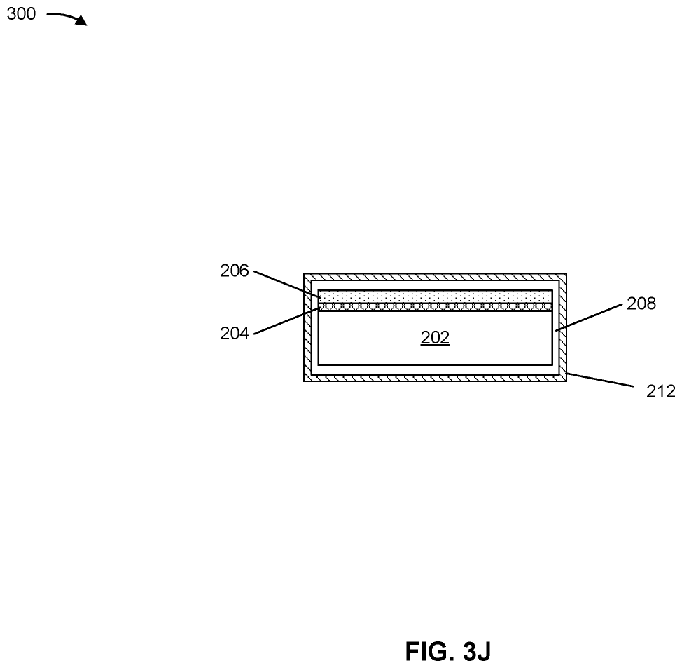

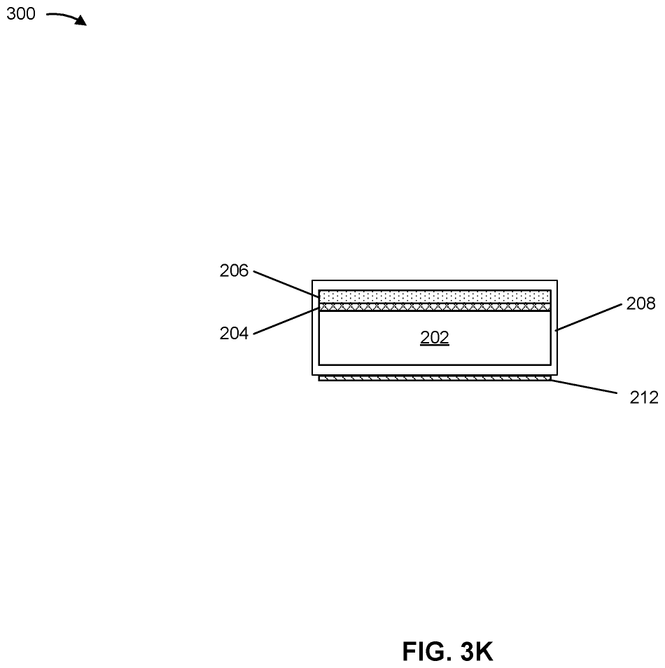

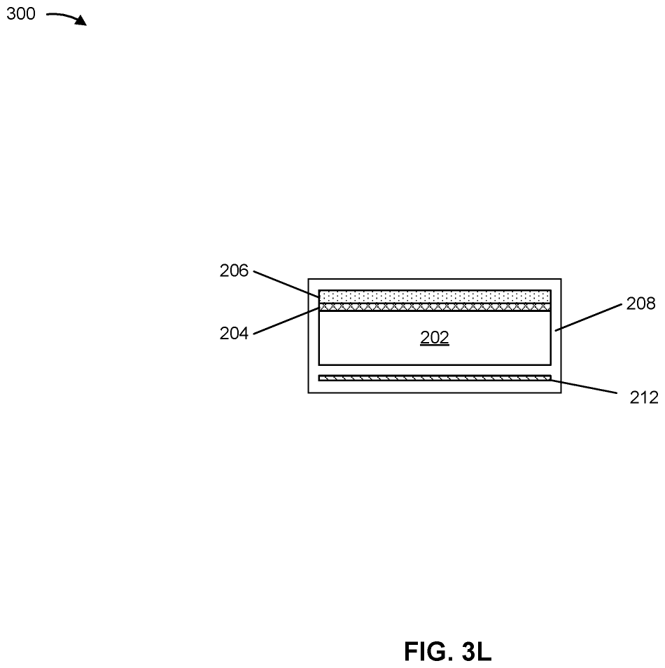

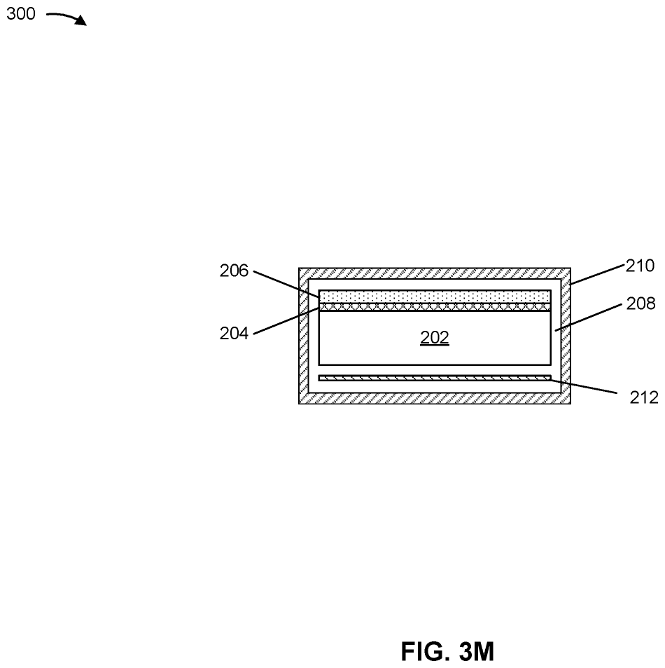

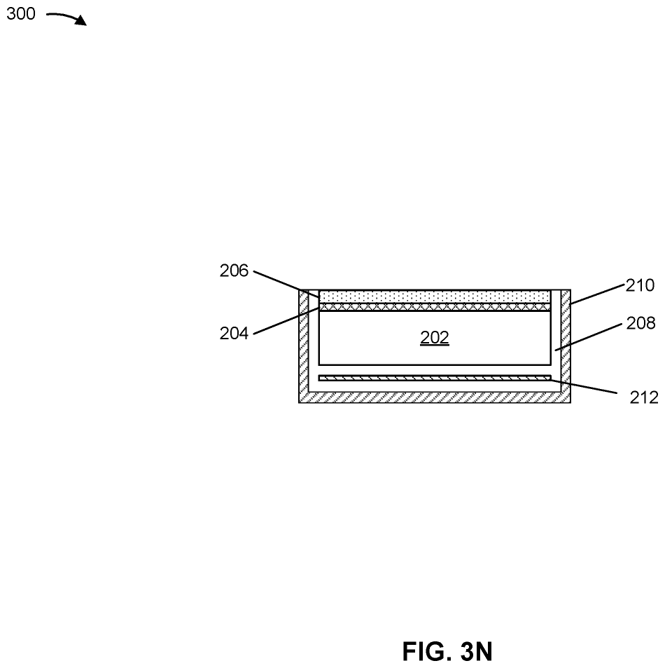

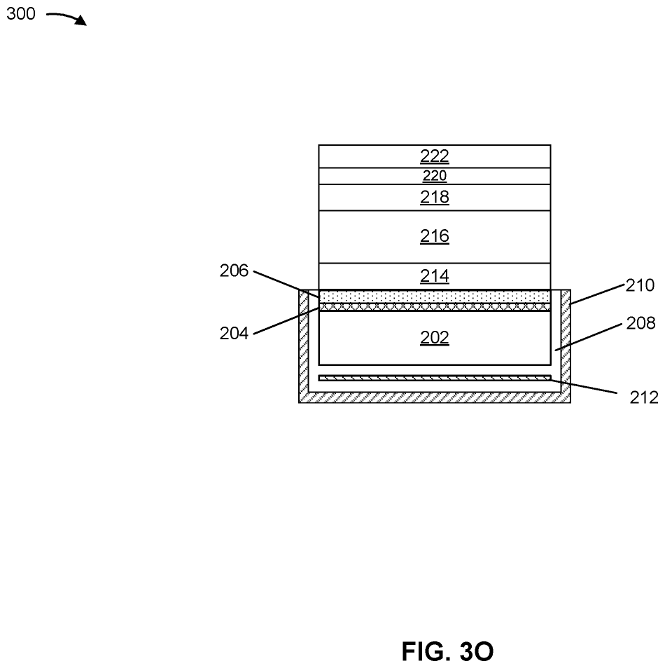

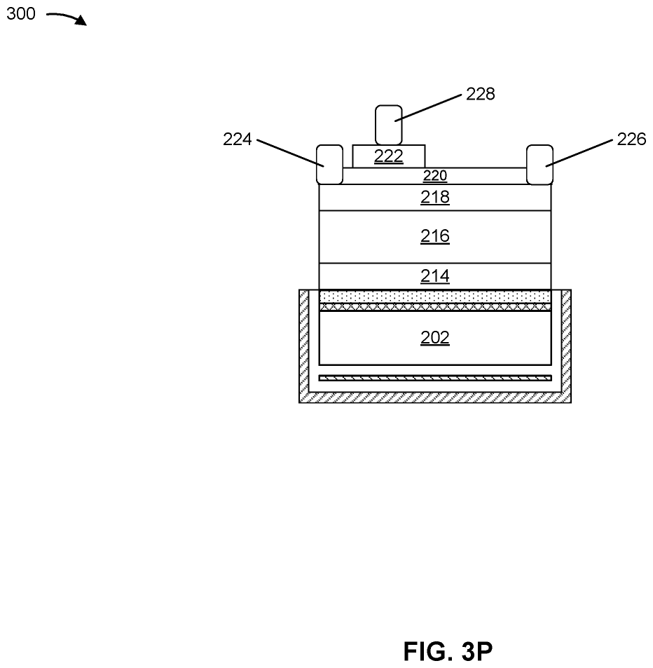

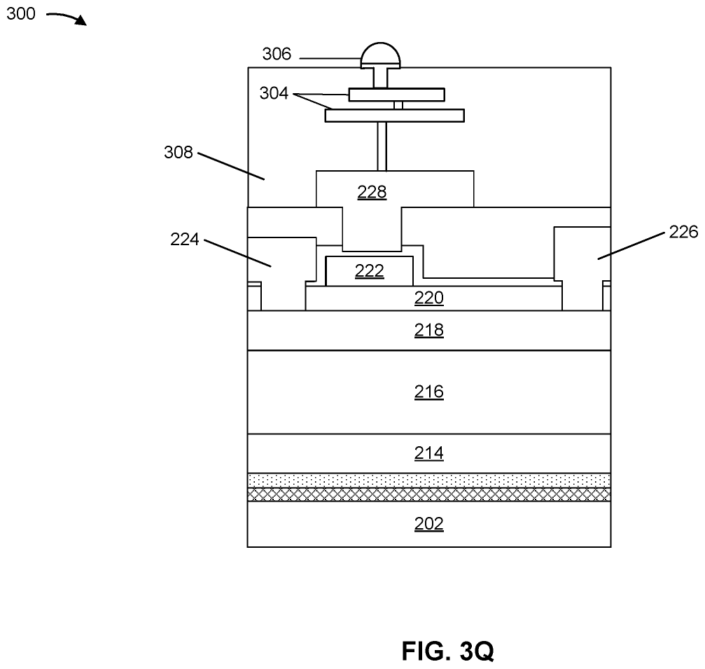

The growth seed layer 206 may be formed over the supporting layer 204, as shown in FIG. 2A. A thickness of the growth seed layer 206 may be less than 0.5 μm. By selecting a thickness of no more than 0.5 μm, any stress caused by CTE difference between the growth seed layer 206 and the substrate 202 remains small. In some implementations, the thickness of the growth seed layer 206 may be in a range from approximately 500 Ångströms (Å) to approximately 3000 Å. By selecting a thickness of at least 500 Å, the growth seed layer 206 allows for epitaxial growth of aluminum nitride on the growth seed layer 206 (e.g., as described in connection with FIG. 3O). By selecting a thickness of no more than 3000 Å, any stress caused by CTE difference between the growth seed layer 206 and the substrate 202 remains small. However, other values for the thickness of the growth seed layer 206 are within the scope of the present disclosure.

The growth seed layer 206 is directly bonded to the supporting layer 204 (e.g., using SAB, as described in connection with FIG. 3F). Therefore, an intervening oxide layer (e.g., a silicon oxide layer) between the supporting layer 204 and the growth seed layer 206 is omitted. As a result, raw materials, power, and time are conserved during formation of the growth seed layer 206. Additionally, any stress caused by CTE difference between the substrate 202 and other layers is reduced because the intervening oxide layer is absent.

A layer 208 of silicon oxide (e.g., SiO₂) may at least partially surround the substrate 202, as shown in FIG. 2A. The layer 208 of silicon oxide may provide adhesion between the substrate 202 and a layer 210 of nitride and adhesion between the substrate 202 and a polycrystalline layer 212. As further shown in FIG. 2A, the layer 210 of nitride may at least partially surround the layer 208 of silicon oxide. In some implementations, the layer 210 includes silicon nitride (e.g., SiN). The layer 210 of nitride may prevent diffusion of atoms out of and/or into the substrate 202 (e.g., from neighboring electronic devices bundled in a same package as the example semiconductor structure 200).

A polycrystalline layer 212 may be included within the layer 208 of silicon oxide. The polycrystalline layer 212 may include polycrystalline silicon. The polycrystalline layer 212 may provide electrostatic adhesion for the example semiconductor structure 200. Therefore, the example semiconductor structure 200 may be tested on a wafer stage that uses electrostatic chuck (e-chuck) to hold the example semiconductor structure 200 onto the wafer stage.

FIG. 2B is a diagram of an example semiconductor structure 230 described herein. The example semiconductor structure 230 is similar to the example semiconductor structure 200, except that a gallium nitride-based electronic structure is formed over the seed layer 206. FIG. 2B shows a transistor as an example of the gallium nitride-based electronic structure. In some implementations, the example semiconductor structure 230 illustrated in FIG. 2B may be included a package with one or more additional electronic devices.

Similar to the example semiconductor structure 200, the example semiconductor structure 230 includes the growth seed layer 206. As shown in FIG. 2B, the growth seed layer 206 supports a gallium nitride-based electronic structure. For example, the gallium nitride-based electronic structure may include an aluminum nitride seed layer 214. The growth seed layer 206 chemically binds to an aluminum nitride precursor such that the aluminum nitride seed layer 214 may be formed by epitaxial growth.

In some implementations, the seed layer 214 also functions as a buffer layer. Although FIG. 2B depicts the seed layer 214 as a single layer, other examples may include multiple seed layers that are arranged to improve lattice matching, reduce threading dislocations, reduce tensile stress, and/or improve a quality of a source 224, a drain 226, and a gate 228.

As further shown in FIG. 2B, the gallium nitride-based electronic structure may include a gallium nitride buffer layer 216. The buffer layer 216 provides improve lattice matching between a remaining portion of the gallium nitride-based electronic structure and the seed layer 214 (as well as the substrate 202).

Some examples may include one or more additional buffer layers (e.g., formed between the buffer layer 216 and the seed layer 214). For example, an additional buffer layer of aluminum gallium nitride (AlGaN) may provide additional lattice matching between the buffer layer 216 and the seed layer 214. In some embodiments, an additional buffer layer of a group III-V material that has varying concentrations for group III and group V elements as a function of depth may be included.

A layer 218 of undoped gallium nitride may provide a channel for the gallium nitride-based electronic structure. The layer 218 of undoped gallium nitride may be formed over the buffer layer 216 such that the effects of lattice mismatch between the gallium nitride of the layer 218 and the aluminum nitride of the seed layer 214 are reduced. In some implementations, the layer 218 may be unintentionally doped gallium nitride (also referred to as “UID-GaN”). For example, the layer 218 may, rather than having intentionally placed dopants, have a doping resulting from process contaminants. In some implementations, the layer 218 has an n-type doping.

A layer 220 of aluminum gallium nitride may be formed over the layer 218 of undoped gallium nitride. Because the layer 220 has a different bandgap than the layer 218, the layers 218 and 220 may form a heterojunction structure for the gallium nitride-based electronic structure. For example, the layer 218 may function as a III-V channel layer with a first bandgap, and the layer 220 may function as a barrier layer with a second bandgap that is different from the first bandgap. Although FIG. 2B depicts the layer 220 as a single layer, other examples may include a stacked barrier layer.

As further shown in FIG. 2B, a source 224 (also referred to as a “source region”) and a drain 226 (also referred to as a “drain region”) are disposed over an upper surface of the heterojunction structure. In some implementations, the source 224 and the drain 226 are arranged at two end locations of the III-V layer 220 of the heterojunction structure. In some implementations, and as shown in FIG. 2B, the source 224 and the drain 226 may extend deeper into the III-V layer 220 and reside at some level within a height of the III-V layer 220. Alternatively, the source 224 and the drain 226 may extend further into the channel formed at an interface between the III-V layer 218 and the III-V layer 220.

Additionally, a gate 228 (also referred to as a “gate region”) may be formed over the heterojunction structure between the source 224 and the drain 226. The gate 228 may include a gate electrode and may be disposed above a gate separation layer 222. The source 224, the drain 226, and the gate 228 are disposed in such a way as to abut a top surface of the III-V layer 220. In some implementations, the gate separation layer 222 comprises an insulator. Alternatively, the gate separation layer 222 comprise a doped III-V material, such as p-doped gallium nitride. The doped material pulls electrons from the channel or donates holes to the channel under the gate 228 in order to form a broken channel (e.g., when the gallium nitride-based electronic structure is a normally off or an E-mode III-N HEMT device). The source 224, the drain 226, and the gate 228 may comprise metals (e.g., titanium, aluminum, nickel, or gold, among other examples) or may comprise a polycrystalline material (e.g., polycrystalline silicon).

During operation, a voltage applied to the gate 228 controls a flow of carriers (e.g., electrons or holes) from the source 224 to the drain 226 through the channel. Accordingly, the gallium nitride-based electronic structure can be controlled by controlling the channel via the gate 228).

FIG. 2C is a diagram of an example semiconductor structure 260 described herein. The example semiconductor structure 260 is similar to the example semiconductor structure 200, except that an oxide layer is formed between the layer 208 of silicon oxide and the layer 212 of polycrystalline silicon. In some implementations, the example semiconductor structure 260 illustrated in FIG. 2C may include, or may be included in, a transistor or another type of electronic device.

Similar to the example semiconductor structure 200, the example semiconductor structure 260 includes the substrate 202 that is at least partially surround by the layer 208 of silicon oxide. As shown in FIG. 2C, a layer 232 of oxide is formed between the layer 208 of silicon oxide and the polycrystalline layer 212. For example, the layer 232 may be formed using an annealing process after formation of the layer 208 of silicon oxide (e.g., as described in connection with FIG. 3I) and before formation of the polycrystalline layer 212 (e.g., as described in connection with FIG. 3J). In some implementations, the annealing is a byproduct from a furnace used to deposit the polycrystalline layer 212.

As indicated above, FIGS. 2A-2C are provided as examples. Other examples may differ from what is described with regard to FIGS. 2A-2C.

FIGS. 3A-3Q are diagrams of an example implementation 300 described herein. Example implementation 300 may be an example process for forming the example semiconductor structure 230 described in connection with FIG. 2B. In some implementations, the example techniques and procedures described in connection with FIGS. 3A-3Q may be used in connection with other semiconductor structures described herein, such as the example semiconductor structure 200 described in connection with FIG. 2A and/or the example semiconductor structure 260 described in connection with FIG. 2C. The example semiconductor structure formed using example implementation 300 may be included in a processor, a memory, or another type of electronic device.

As shown in FIG. 3A, the example process for forming the semiconductor structure may be performed in connection with a substrate 202. The substrate 202 may include a semiconductor die substrate, a semiconductor wafer, a stacked semiconductor wafer, or another type of substrate in which semiconductor pixels may be formed. For example, the substrate 202 may be formed of aluminum nitride (AlN), such as ceramic AlN. In some implementations, a surface roughness of the substrate 202 may be in a range from approximately 20 nm to approximately 30 nm. However, other values for the surface roughness of the substrate 202 are within the scope of the present disclosure.

As shown in FIG. 3B, a supporting layer 204 may be formed over the substrate 202. For example, the deposition tool 102 may form the supporting layer 204 over and/or on a frontside surface of the substrate 202. In some implementations, the supporting layer 204 may be a sputtered layer such that the deposition tool 102 forms the supporting layer 204 using a sputtering technique. Accordingly, the supporting layer 204 may comprise sputtered aluminum nitride or sputtered amorphous silicon. Alternatively, the deposition tool 102 forms the supporting layer 204 using a CVD technique. Accordingly, the supporting layer 204 may comprise amorphous silicon formed via CVD.

As shown in FIG. 3C, the supporting layer 204 may be planarized. For example, the planarization tool 110 may perform a CMP process on the supporting layer 204. Accordingly, a thickness of the supporting layer 204 may be reduced to a range from approximately 0.1 μm to approximately 1.0 μm, as described above. However, other values for the thickness of the supporting layer 204 are within the scope of the present disclosure. Additionally, the CMP process may result in a surface roughness of the supporting layer 204 less than 0.7 nm. Because the surface roughness of the supporting layer 204 is significant less than the surface roughness of the substrate 202, the supporting layer 204 helps other layers (e.g., growth seed layer 206) adhere to the substrate 202. However, other values for the surface roughness of the supporting layer 204 are within the scope of the present disclosure.

As shown in FIG. 3D, the example process for forming the semiconductor structure may further be performed in connection with a substrate 302. The substrate 302 may include a semiconductor die substrate, a semiconductor wafer, a stacked semiconductor wafer, or another type of substrate in which semiconductor pixels may be formed. For example, the substrate 302 may be formed of silicon (Si). In some implementations, the substrate 302 may be a p+ substrate and may have a (111) lattice structure.

As shown in FIG. 3E, a growth seed layer 206 may be formed over the substrate 302. For example, the deposition tool 102 may form the growth seed layer 206 over and/or on a frontside surface of the substrate 302. In some implementations, the growth seed layer 206 may comprise silicon (Si), such as p− silicon. Accordingly, the deposition tool 102 may form the growth seed layer 206 using epitaxial growth on the substrate 302. The deposition tool 102 may form the growth seed layer 206 using epitaxial growth such that the growth seed layer 206 is formed to have a particular lattice structure or grain orientation, such as a (111) lattice structure or grain orientation. Thus, the growth seed layer 206 may be referred to as a p− Si(111) growth seed layer.

As shown in FIG. 3F, the growth seed layer 206 is bonded to the supporting layer 204 (and thus the supporting layer is also referred to as a “bonding layer”). The growth seed layer 206 may be directly bonded to the supporting layer 204 via SAB. For example, the exposure tool 104 may expose the supporting layer 204 to a plasma (e.g., an argon (Ar) plasma or another plasma formed of ions or neutral atoms) to create dangling bonds on a surface (e.g., a frontside surface) of the supporting layer 204. Accordingly, the growth seed layer 206 bonds to the dangling bonds of the supporting layer 204 when brought into physical contact with the supporting layer 204 in a vacuum environment. In some implementations, the annealing tool 116 may heat the vacuum environment to promote adhesion between the growth seed layer 206 and the dangling bonds of the supporting layer 204.

As shown in FIG. 3G, a thickness of the substrate 302 is reduced. For example, the etch tool 108 may perform wafer grinding on the substrate 302 to reduce a height of the substrate 302. In some implementations, the substrate 302 is reduced to a thickness of no more than 26 μm. By selecting a thickness of no more than 26 μm, the substrate 302 may be fully removed by a subsequent wet etch process (e.g., as described in connection with FIG. 3H). However, other values for the thickness of the substrate 302 are within the scope of the present disclosure.

As shown in FIG. 3H, the substrate 302 is removed. For example, the etch tool 108 may perform a wet etch process (e.g., using a hydrofluoric, nitric, acetic (HNA) mixture) on the substrate 302 to dissolve the substrate 302. In some implementations, the etch tool 108 may use an etchant that etches p+ silicon at a faster rate than p− silicon. As a result, the substrate 302 is removed while the growth seed layer 206 remains. For example, the growth seed layer 206 may have a thickness of no more than 0.5 μm (e.g., in a range from approximately 500 Å to approximately 3000 Å), as described above.

As shown in FIG. 3I, a layer 208 of silicon oxide may be formed around the substrate 202 and over the growth seed layer 206. For example, the deposition tool 102 may form the layer 208 of silicon oxide using a spin-coating technique, a CVD technique, a PVD technique, an ALD technique, and/or another deposition technique. Additionally, as shown in FIG. 3J, a layer 212 of polycrystalline silicon may be formed around the layer 208 of silicon oxide. For example, the deposition tool 102 may form the layer 212 of polycrystalline silicon using a spin-coating technique, a CVD technique, a PVD technique, an ALD technique, and/or another deposition technique.

In some implementations, the layer 212 of polycrystalline silicon is deposited via furnace. For example, the deposition tool 102 may form the layer 212 of polycrystalline silicon using a furnace that is heated to a temperature in a range from approximately 720 degrees Celsius (C) to approximately 850° C. By selecting a temperature of at least 720° C., a deposition rate of polycrystalline silicon is fast enough to form the layer 212 of polycrystalline silicon. By selecting a temperature of no more than 850° C., irregularities in the layer 212 of polycrystalline silicon are reduced. However, other values for the temperature of the furnace are within the scope of the present disclosure. Therefore, in some implementations, an additional layer of oxide (e.g., layer 232, as described in connection with FIG. 2C) may be formed as a byproduct of the formation of the layer 212 of polycrystalline silicon. For example, the furnace may anneal the layer 208 of silicon oxide and form additional oxide (e.g., additional silicon oxide) thereon.

As shown in FIG. 3K, a portion of the layer 212 of polycrystalline silicon is removed. For example, a portion of the layer 212 is removed such that a remaining portion of the layer 212 is below the substrate 202. For example, the etch tool 108 may perform a wet etch process (e.g., using a tetramethylammonium hydroxide (TMAH) solution and/or an ammonium hydroxide (NH₄OH) solution) on the layer 212 to dissolve a portion of the layer 212 that is above, and adjacent to, the substrate 202. The etch tool 108 may use a solution that is approximately 2.3% TMAH or a solution that is in a range from approximately 10% ammonium hydroxide to approximately 30% ammonium hydroxide. By selecting a solution that is 2.3% TMAH or at least 10% ammonium hydroxide, the layer 212 of polycrystalline silicon is dissolved fast enough to be removed from the frontside of the substrate 202. By selecting a solution that is 2.3% TMAH or no more than 30% ammonium hydroxide, a remaining portion of the layer 212 below the substrate 202 is thick enough to allow for use of an e-chuck, as described in connection with FIG. 2A.

As shown in FIG. 3L, additional silicon oxide may be formed to increase a thickness of the layer 208. For example, the additional silicon oxide may be deposited to grow the layer 208 around the substrate 202, over the remaining portion of the layer 212 of polycrystalline silicon, and over the growth seed layer 206. The deposition tool 102 may form the additional silicon oxide using a spin-coating technique, a CVD technique, a PVD technique, an ALD technique, and/or another deposition technique. Additionally, as shown in FIG. 3M, a layer 210 of silicon nitride may be formed around the layer 208 of silicon oxide. For example, the deposition tool 102 may form the layer 210 of silicon nitride using a spin-coating technique, a CVD technique, a PVD technique, an ALD technique, and/or another deposition technique.

As shown in FIG. 3N, a portion of the layer 210 of silicon nitride is removed. For example, a portion of the layer 210 is removed such that a remaining portion of the layer 210 is adjacent to, and below, the substrate 202. For example, the etch tool 108 may perform a wet etch process (e.g., using a phosphoric acid (H₃PO₄) solution) on the layer 210 to dissolve a portion of the layer 210 that is over the growth seed layer 206. The etch tool 108 may use a solution that is at least approximately 90% phosphoric acid. By selecting a solution that is at least 90% phosphoric acid, the layer 210 of silicon nitride is dissolved fast enough to be removed from above the growth seed layer 206.

As further shown in FIG. 3N, a portion of the layer 208 of silicon oxide is removed. For example, a portion of the layer 208 is removed such that a remaining portion of the layer 208 is adjacent to, and below, the substrate 202. For example, the etch tool 108 may perform a wet etch process (e.g., using a hydrofluoric acid (HF) solution) on the layer 208 to dissolve a portion of the layer 208 that is over the growth seed layer 206. The etch tool 108 may use a solution that is in a range from approximately 0.5% to hydrofluoric acid to approximately 49% hydrofluoric acid. By selecting a solution that is at least 0.5% hydrofluoric acid, the layer 208 of silicon oxide is dissolved fast enough to be removed from above the growth seed layer 206. By selecting a solution that is no more than 49% hydrofluoric acid, other layers remain undamaged by the wet etch process.

As shown in FIG. 3O, a seed layer 214 may be formed using the growth seed layer 206. For example, the deposition tool 102 may form the seed layer 214 over and/or on a frontside surface of the substrate 202. In some implementations, the seed layer 214 may comprise aluminum nitride. Accordingly, the deposition tool 102 may form the seed layer 214 using epitaxial growth on the growth seed layer 206.

As further shown in FIG. 3O, one or more buffer layers may be formed. In the example implementation 300, a buffer layer 216 is formed over the seed layer 214. The deposition tool 102 may form the buffer layer 216 over and/or on a frontside surface of the substrate 202. In some implementations, the buffer layer 216 may comprise gallium nitride. Accordingly, the deposition tool 102 may form the buffer layer 216 using epitaxial growth on the seed layer 214.

Additionally, a heterojunction structure (e.g., formed of III-V materials) may be deposited over the buffer layer 216. For example, the heterojunction structure may include a layer 218 formed of a III-V material with a first bandgap (e.g., undoped GaN or UID-GaN) and a layer 220 formed of a III-V material with a second bandgap (e.g., AlGaN). The deposition tool 102 may form the layers 218 and 220 using a spin-coating technique, a CVD technique, a PVD technique, an ALD technique, and/or another deposition technique.

As further shown in FIG. 3O, a doped layer 222 (e.g., formed of doped III-V material) may be deposited over the heterojunction structure. In some implementations, the doped layer 222 comprises n-doped or p-doped GaN. The deposition tool 102 may form the layer 222 using a spin-coating technique, a CVD technique, a PVD technique, an ALD technique, and/or another deposition technique. Additionally, the ion implantation tool 114 may implant p-type dopants or n-type dopants into the layer 222 after the layer 222 is formed.

As shown in FIG. 3P, a high-electron-mobility transistor (HEMT) process may be performed. For example, a source 224 and a drain 226 may be formed over the heterojunction structure. The deposition tool 102 may form the source 224 and the drain 226 using a spin-coating technique, a CVD technique, a PVD technique, an ALD technique, and/or another deposition technique.

As further shown in FIG. 3P, the HEMT process may further include a gate 228 being formed over the layer 222. The deposition tool 102 may form the gate 228 using a spin-coating technique, a CVD technique, a PVD technique, an ALD technique, and/or another deposition technique.

In some implementations, as shown in FIG. 3Q, the example semiconductor structure 230 may be prepared for packaging. For example, metallization layers 304 may be formed to connect to the gate 228. Additionally, in some implementations, metallization layers may be formed to connect to the source 224 and/or the drain 226. The metallization layers 304 may be formed of materials such as a gold (Au) material, a copper (Cu) material, a silver (Ag) material, a nickel (Ni) material, a tin (Sn) material, and/or a palladium (Pd) material, among other examples. The metallization layers 304 may include metal lines, vias, interconnects, and/or another type of metallization layers.

A bump metal layer 306 may be formed over a top surface of a dielectric region 308 including the metallization layers 304. The bump metal layer 306 may be electrically connected and/or physically connected with the metallization layers 304. The bump metal layer 306 may be included in recesses in the top surface of the dielectric region 308. The bump metal layer 306 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more metal alloys, one or more conductive ceramics, and/or another type of conductive materials.

Additionally, in some implementations, a front side of the semiconductor structure may be bonded to a carrier substrate or blue tape. Therefore, the layer 208 of silicon oxide, the layer 210 of silicon nitride, and/or the layer 212 of polycrystalline silicon may be removed. Additionally, the substrate 202 may be reduced or removed. For example, a laser process may be performed on a back side of the semiconductor structure to perform liftoff at least a portion of the substrate 202, along with the layers 208, 210, and 212.

By using techniques as described in connection with FIGS. 3A-3Q, the growth seed layer 206 allows for epitaxy of gallium nitride over the aluminum nitride substrate without exacerbating CTE mismatch between silicon and the gallium nitride-based electronic structure. As a result, defects in the drain 226 are reduced, and bowing and cracking of the substrate 202 is reduced, which improves performance of a transistor including the drain 226. Additionally, the growth seed layer 206 is formed using SAB, which is faster than other techniques as well as conserving power, processing resources, and raw materials that otherwise would have been expended in forming the growth seed layer 206.

As indicated above, FIGS. 3A-3Q are provided as an example. Other examples may differ from what is described with regard to FIGS. 3A-3Q.

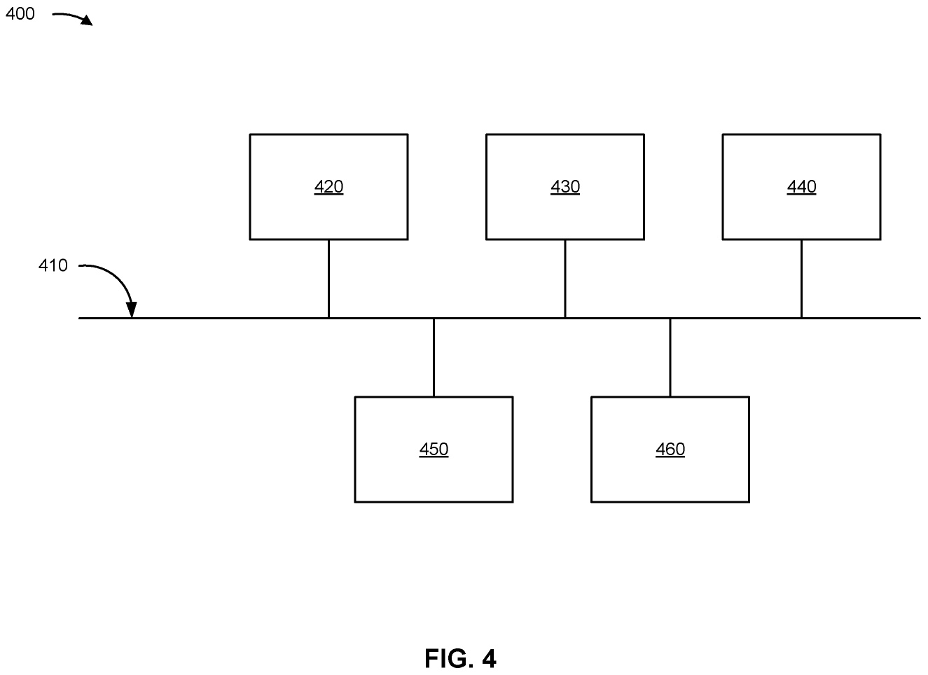

FIG. 4 is a diagram of example components of a device 400 described herein. In some implementations, one or more of the semiconductor processing tools 102-116 and/or the wafer/die transport tool 118 may include one or more devices 400 and/or one or more components of device 400. As shown in FIG. 4, device 400 may include a bus 410, a processor 420, a memory 430, an input component 440, an output component 450, and a communication component 460.

Bus 410 may include one or more components that enable wired and/or wireless communication among the components of device 400. Bus 410 may couple together two or more components of FIG. 4, such as via operative coupling, communicative coupling, electronic coupling, and/or electric coupling. Processor 420 may include a central processing unit, a graphics processing unit, a microprocessor, a controller, a microcontroller, a digital signal processor, a field-programmable gate array, an application-specific integrated circuit, and/or another type of processing component. Processor 420 is implemented in hardware, firmware, or a combination of hardware and software. In some implementations, processor 420 may include one or more processors capable of being programmed to perform one or more operations or processes described elsewhere herein.

Memory 430 may include volatile and/or nonvolatile memory. For example, memory 430 may include random access memory (RAM), read only memory (ROM), a hard disk drive, and/or another type of memory (e.g., a flash memory, a magnetic memory, and/or an optical memory). Memory 430 may include internal memory (e.g., RAM, ROM, or a hard disk drive) and/or removable memory (e.g., removable via a universal serial bus connection). Memory 430 may be a non-transitory computer-readable medium. Memory 430 stores information, instructions, and/or software (e.g., one or more software applications) related to the operation of device 400. In some implementations, memory 430 may include one or more memories that are coupled to one or more processors (e.g., processor 420), such as via bus 410.

Input component 440 enables device 400 to receive input, such as user input and/or sensed input. For example, input component 440 may include a touch screen, a keyboard, a keypad, a mouse, a button, a microphone, a switch, a sensor, a global positioning system sensor, an accelerometer, a gyroscope, and/or an actuator. Output component 450 enables device 400 to provide output, such as via a display, a speaker, and/or a light-emitting diode. Communication component 460 enables device 400 to communicate with other devices via a wired connection and/or a wireless connection. For example, communication component 460 may include a receiver, a transmitter, a transceiver, a modem, a network interface card, and/or an antenna.

Device 400 may perform one or more operations or processes described herein. For example, a non-transitory computer-readable medium (e.g., memory 430) may store a set of instructions (e.g., one or more instructions or code) for execution by processor 420. Processor 420 may execute the set of instructions to perform one or more operations or processes described herein. In some implementations, execution of the set of instructions, by one or more processors 420, causes the one or more processors 420 and/or the device 400 to perform one or more operations or processes described herein. In some implementations, hardwired circuitry is used instead of or in combination with the instructions to perform one or more operations or processes described herein. Additionally, or alternatively, processor 420 may be configured to perform one or more operations or processes described herein. Thus, implementations described herein are not limited to any specific combination of hardware circuitry and software.

The number and arrangement of components shown in FIG. 4 are provided as an example. Device 400 may include additional components, fewer components, different components, or differently arranged components than those shown in FIG. 4. Additionally, or alternatively, a set of components (e.g., one or more components) of device 400 may perform one or more functions described as being performed by another set of components of device 400.

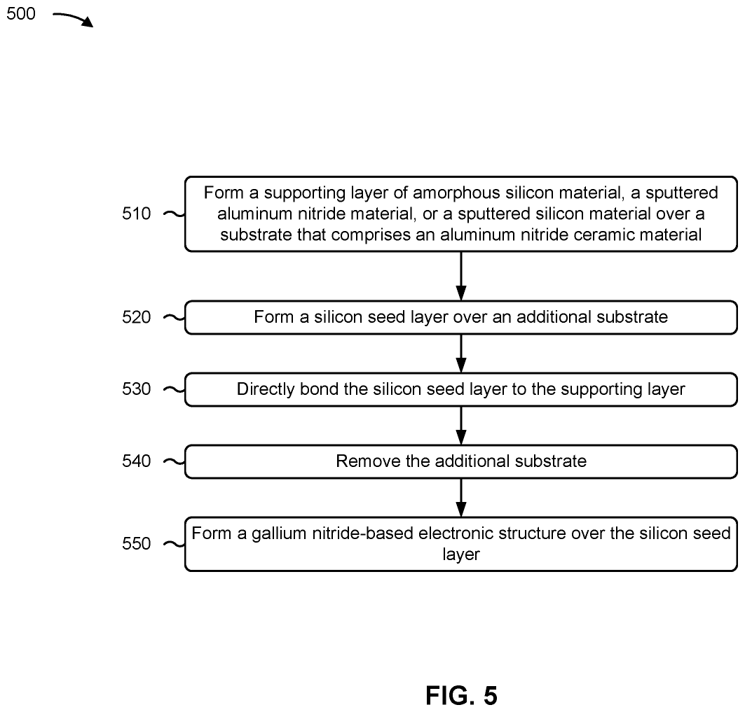

FIG. 5 is a flowchart of an example process 500 associated with forming ceramic substrate structures described herein. In some implementations, one or more process blocks of FIG. 5 are performed by one or more semiconductor processing tools (e.g., one or more of the semiconductor processing tools 102-116). Additionally, or alternatively, one or more process blocks of FIG. 5 may be performed by one or more components of device 400, such as processor 420, memory 430, input component 440, output component 450, and/or communication component 460.

As shown in FIG. 5, process 500 may include forming a supporting layer of amorphous silicon material, sputtered aluminum nitride material, or sputtered silicon material over a first substrate that comprises an aluminum nitride ceramic material (block 510). For example, one or more of the semiconductor processing tools 102-116 may form a supporting layer 204 of amorphous silicon material, sputtered aluminum nitride material, or sputtered silicon material over a first substrate 202 that comprises an aluminum nitride ceramic material, as described herein.

As further shown in FIG. 5, process 500 may include forming a silicon seed layer over a second substrate (block 520). For example, one or more of the semiconductor processing tools 102-116 may form a silicon seed layer 206 over a second substrate 302, as described herein.

As further shown in FIG. 5, process 500 may include directly bonding the silicon seed layer to the supporting layer (block 530). For example, one or more of the semiconductor processing tools 102-116 may directly bond the silicon seed layer 206 to the supporting layer 204, as described herein.

As further shown in FIG. 5, process 500 may include removing the second substrate (block 540). For example, one or more of the semiconductor processing tools 102-116 may remove the second substrate 302, as described herein.

As further shown in FIG. 5, process 500 may include forming a gallium nitride-based electronic structure over the silicon seed layer (block 550). For example, one or more of the semiconductor processing tools 102-116 may form a gallium nitride-based electronic structure 224/226/228 over the silicon seed layer 206, as described herein.

Process 500 may include additional implementations, such as any single implementation or any combination of implementations described below and/or in connection with one or more other processes described elsewhere herein.

In a first implementation, directly bonding the silicon seed layer 206 to the supporting layer 204 includes performing SAB using a plasma.

In a second implementation, alone or in combination with the first implementation, directly removing the second substrate 302 includes performing wafer grinding on the second substrate 302 to reduce a height of the second substrate 302 and performing a wet etching process to remove the second substrate 302.

In a third implementation, alone or in combination with one or more of the first and second implementations, process 500 includes forming a layer 208 of silicon oxide surrounding a portion of the first substrate 202, forming a layer 212 of polycrystalline silicon surrounding the layer 208 of silicon oxide, and removing a portion of the layer 212 of polycrystalline silicon such that a remaining portion of the layer 212 of polycrystalline silicon is below the first substrate 302.

In a fourth implementation, alone or in combination with one or more of the first through third implementations, process 500 includes forming an oxide layer 232 between the layer 208 of silicon oxide and the layer 212 of polycrystalline silicon using an annealing process.

In a fifth implementation, alone or in combination with one or more of the first through fourth implementations, process 500 includes depositing additional silicon oxide to grow the layer 208 of silicon oxide and forming a layer 210 of silicon nitride surrounding the layer 208 of silicon oxide.

In a sixth implementation, alone or in combination with one or more of the first through fifth implementations, process 500 includes removing a portion of the layer 210 of silicon nitride formed over the silicon seed layer 206 and removing a portion of the layer 208 of silicon oxide formed over the silicon seed layer 206.

In a seventh implementation, alone or in combination with one or more of the first through sixth implementations, process 500 includes performing a CMP on the supporting layer 204 before directly bonding the silicon seed layer 206 to the supporting layer 204.

In an eighth implementation, alone or in combination with one or more of the first through seventh implementations, forming the gallium nitride-based electronic structure 224/226/228 comprises performing gallium nitride epitaxial growth and performing an HEMT process to form a source 224, a drain 226, and a gate 228.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

In this way, using SAB allows direct bonding of a silicon growth seed layer over an aluminum nitride substrate without an intervening oxide layer. The growth seed layer may include p− Si(111) in order to allow for epitaxy of gallium nitride without exacerbating CTE mismatch between silicon and the gallium nitride. As a result, defects in the gallium nitride are reduced, and bowing and cracking of the substrate is reduced, which improves performance of an electronic device including the gallium nitride. Additionally, using SAB is faster than other techniques for forming a growth seed layer as well as conserving power, processing resources, and raw materials that otherwise would have been expended in forming the growth seed layer.

As described in greater detail above, some implementations described herein provide a semiconductor structure. The semiconductor structure includes a substrate comprising an aluminum nitride ceramic material. The semiconductor structure includes a silicon seed layer over the substrate without an intervening oxide layer between the silicon seed layer and the substrate. The semiconductor structure includes a gallium nitride-based electronic structure over the silicon seed layer.

As described in greater detail above, some implementations described herein provide a method. The method includes forming a supporting layer of amorphous silicon material, sputtered aluminum nitride material, or sputtered silicon material over a first substrate that comprises an aluminum nitride ceramic material. The method includes forming a silicon seed layer over a second substrate. The method includes directly bonding the silicon seed layer to the supporting layer. The method includes removing the second substrate. The method includes forming a gallium nitride-based electronic structure over the silicon seed layer.

As described in greater detail above, some implementations described herein provide a semiconductor device. The semiconductor device includes a substrate comprising an aluminum nitride ceramic material. The semiconductor device includes a sputtered layer over the substrate. The semiconductor device includes a silicon seed layer over the sputtered layer and directly bonded to the sputtered layer. The semiconductor device includes a buffer layer over the silicon seed layer. The semiconductor device includes a source over the buffer layer. The semiconductor device includes a drain comprising a gallium nitride material over the buffer layer. The semiconductor device includes a gate over the buffer layer.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate comprising an aluminum nitride;
a silicon seed layer over the substrate without a silicon oxide layer between the silicon seed layer and the substrate; and
a gallium nitride-based electronic structure over the silicon seed layer.

2. The semiconductor structure of claim 1, further comprising:
a layer of sputtered aluminum nitride material or sputtered silicon material between the silicon seed layer and the substrate.

3. The semiconductor structure of claim 1, further comprising:
a layer of amorphous silicon between the silicon seed layer and the substrate.

4. The semiconductor structure of claim 1, further comprising:
a layer of silicon oxide surrounding a portion of the substrate.

5. The semiconductor structure of claim 4, further comprising:
an oxide layer formed between portions of the silicon oxide.

6. The semiconductor structure of claim 1, further comprising:
a layer of polycrystalline silicon below the substrate.

7. The semiconductor structure of claim 1, further comprising:
a layer of silicon nitride surrounding a portion of the substrate.

8. The semiconductor structure of claim 1, wherein the silicon seed layer comprises p− silicon.

9. A method, comprising:
forming a supporting layer of amorphous silicon material, sputtered aluminum nitride material, or sputtered silicon material over a first substrate that comprises an aluminum nitride ceramic material;
forming a silicon seed layer over a second substrate;
directly bonding the silicon seed layer to the supporting layer;
removing the second substrate; and
forming a gallium nitride-based electronic structure over the silicon seed layer.

10. The method of claim 9, wherein directly bonding the silicon seed layer to the supporting layer comprises:
performing surface activated bonding using a plasma.

11. The method of claim 9, wherein directly removing the second substrate comprises:
performing wafer grinding on the second substrate to reduce a height of the second substrate; and
performing a wet etching process to remove the second substrate.

12. The method of claim 9, further comprising:
forming a layer of silicon oxide surrounding a portion of the first substrate;
forming a layer of polycrystalline silicon surrounding the layer of silicon oxide; and
removing a portion of the layer of polycrystalline silicon such that a remaining portion of the layer of polycrystalline silicon is below the first substrate.

13. The method of claim 12, further comprising:
forming an oxide layer between the layer of silicon oxide and the layer of polycrystalline silicon using an annealing process.

14. The method of claim 12, further comprising:
depositing additional silicon oxide to grow the layer of silicon oxide; and
forming a layer of silicon nitride surrounding the layer of silicon oxide.

15. The method of claim 14, further comprising:
removing a portion of the layer of silicon nitride formed over the silicon seed layer; and
removing a portion of the layer of silicon oxide formed over the silicon seed layer.

16. The method of claim 9, further comprising:
performing a chemical mechanical polishing on the supporting layer before directly bonding the silicon seed layer to the supporting layer.

17. The method of claim 9, wherein forming the gallium nitride-based electronic structure comprises:
performing gallium nitride epitaxial growth; and
performing a high-electron-mobility transistor (HEMT) process to form a source, a drain, and a gate.

18. A semiconductor device, comprising:
a substrate comprising an aluminum nitride;
a bonding layer over the substrate;
a silicon seed layer over the bonding layer and directly bonded to the bonding layer;
a buffer layer over the silicon seed layer;
a source over the buffer layer;
a drain comprising a gallium nitride material over the buffer layer; and
a gate over the buffer layer.

19. The semiconductor device of claim 18, wherein the silicon seed layer comprises p− silicon.

20. The semiconductor device of claim 18, wherein the bonding layer comprises aluminum nitride or silicon.
